(19) United States
(12) Patent Application Publication
(10) Pub. No.: US 2025/0234733 A1
(43) Pub. Date: Jul. 17, 2025

(54) DISPLAY PANEL AND DISPLAY DEVICE

(71) Applicant: KunShan Go-Visionox Opto-Electronics Co., Ltd, Kunshan (CN)

(72) Inventors: Junhui LOU, Kunshan (CN); Xu QIN, Kunshan (CN); Dongyu QI, Kunshan (CN); Pengle DANG, Kunshan (CN); Zeshang HE, Kunshan (CN)

(73) Assignee: KunShan Go-Visionox Opto-Electronics Co., Ltd, Kunshan (CN)

(21) Appl. No.: 19/171,342

(22) Filed: Apr. 6, 2025

Related U.S. Application Data
(63) Continuation of application No. PCT/CN2023/074178, filed on Feb. 2, 2023.

(30) Foreign Application Priority Data
Nov. 10, 2022 (CN) 202211407683.3

(51) Int. Cl. H10K 59/131; H10K 59/121; H10K 59/65

(52) U.S. Cl. CPC H10K 59/131; H10K 59/1216; H10K 59/65

(57) ABSTRACT

The present application provides a display panel and a display device. The display panel has a first area and a second area. The display panel includes a first pixel unit, a second pixel unit, a first pixel circuit, a second pixel circuit, and a first wire. The first pixel unit and the second pixel unit are both located in the first area, and the first pixel circuit is located in the second area and connected to the first pixel unit. The second pixel circuit is located in the second area and connected to the second pixel unit, and a distance between the second pixel circuit and the second pixel unit is greater than a distance between the first pixel circuit and the first pixel unit. The first wire is at least partially configured to connect the first pixel unit and the first pixel circuit.

### CROSS-REFERENCE TO RELATED APPLICATIONS

The present application is a continuation of International Patent Application No. PCT/CN2023/074178, filed on Feb. 2, 2023, which claims priority to Chinese Patent Application No. 202211407683.3 filed on Nov. 10, 2022, disclosures of both of which are incorporated herein by reference in their entireties.

### FIELD

The present application relates to the field of display, and in particular to a display panel and a display device.

### BACKGROUND

With the rapid development of electronic devices, users have higher and higher requirements for screen-to-body ratio, making the full-screen display of the electronic devices attract more and more attention in the industry.

In order to realize different functions of a display panel, it is necessary to integrate components such as a front camera, a receiver and an infrared sensing element in a photosensitive region of the display panel. In order to achieve the effect of full-screen display, it is necessary to provide a pixel structure in the photosensitive region. However, due to the limitation of the photosensitive region, the layout of traces connected to the pixel structure is affected, thus making the display panel prone to problems such as non-uniform display.

### SUMMARY

Embodiments of the present application provide a display panel and a display device, which can improve display uniformity.

An embodiment of the present application provides a display panel having a first area and a second area. The first area has a transmittance greater than the transmittance of the second area. The display panel includes a first pixel unit, a second pixel unit, a first pixel circuit, a second pixel circuit, and a first wire.

The first pixel unit and the second pixel unit are both located in the first area, and the first pixel circuit is located in the second area and connected to the first pixel unit. The second pixel circuit is located in the second area and connected to the second pixel unit, and a distance between the second pixel circuit and the second pixel unit is greater than a distance between the first pixel circuit and the first pixel unit. The first wire is at least partially configured to connect the first pixel unit and the first pixel circuit, and the first wire has a length greater than the distance between the first pixel circuit and the first pixel unit.

One embodiment of the present application provides a display device, including a display panel in any one of the above embodiments.

The embodiments of the present application provide a display panel and a display device, in which the length of the first wire is increased to be greater than the distance between the first pixel circuit and the first pixel unit, and the value of capacitance corresponding to the first wire is greater than the value of capacitance corresponding to a trace used to connect the first pixel circuit and the first pixel unit. Such a design can reduce the difference in the lengths of the respective trace of the first pixel unit and the respective trace of the second pixel unit, thereby reducing the difference in the values of capacitance corresponding thereto, reducing the difference in charging time between the first pixel unit and the second pixel unit, making the luminous brightness of the first pixel unit close to that of the second pixel unit, and improving the display uniformity of the first area.

### BRIEF DESCRIPTION OF THE DRAWINGS

In order to describe the embodiments of the present application more clearly, the accompanying drawings required for illustration of the embodiments of the present application will be briefly described below. The accompanying drawings described below show merely some of the embodiments of the present application, and other drawings from the accompanying drawings may be derived.

FIG. 1 is a schematic top view of a display panel according to an embodiment of the present application;

FIG. 2 is a structural schematic partial enlarged view of a region Q in FIG. 1;

FIG. 3 is a structural schematic partial enlarged view of the region Q in FIG. 1 in another example;

FIG. 4 is a structural schematic diagram of the connection between a pixel circuit and a pixel unit of a display panel according to an embodiment of the present application;

FIG. 5 is a structural schematic diagram of the connection between a pixel circuit and a pixel unit of another display panel according to an embodiment of the present application;

FIG. 6 is a structural schematic diagram of the connection between a pixel circuit and a pixel unit of still another display panel according to an embodiment of the present application;

FIG. 7 is a structural schematic diagram of the connection between a pixel circuit and a pixel unit of a further display panel according to an embodiment of the present application;

FIG. 8 is a structural schematic diagram of the connection between a pixel circuit and a pixel unit of a still further display panel according to an embodiment of the present application;

FIG. 9 is a structural schematic diagram of the connection between a pixel circuit and a pixel unit of a yet further display panel according to an embodiment of the present application;

FIG. 10 is a structural schematic diagram of the connection between a pixel circuit and a pixel unit of another further display panel according to an embodiment of the present application;

FIG. 11 is a structural schematic diagram of the connection between a pixel circuit and a pixel unit of still another further display panel according to an embodiment of the present application;

FIG. 12 is a structural schematic diagram of the connection between a pixel circuit and a pixel unit of yet another further display panel according to an embodiment of the present application;

FIG. 13 is a structural schematic diagram of the connection between a pixel circuit and a pixel unit of still yet another further display panel according to an embodiment of the present application; and

FIG. 14 is a schematic structural diagram of a display device according to an embodiment of the present application.

### DETAILED DESCRIPTION OF EMBODIMENTS

The implementations of the present application are further described in detail below with reference to the accompanying drawings and embodiments. The following detailed description of the embodiments and the accompanying drawings are used to illustrate the principle of the present application in an exemplary manner, but shall not be used to limit the scope of the present application. That is, the present application is not limited to the described embodiments.

It should be noted that, herein, relative terms such as “first” and “second” are only used to distinguish one entity or operation from another entity or operation, and do not necessarily require or imply that such an actual relationship or order exists between these entities or operations. Moreover, the terms “include”, “comprise”, or any other variants thereof are intended to cover a non-exclusive inclusion, and a process, a method, an article, or a device that includes a list of elements not only includes those elements but also includes other elements that are not listed, or further includes elements inherent to such a process, method, article, or device. When no more limitations are made, an element limited by “comprising . . . ” does not exclude other identical elements existing in the process, the method, the article, or the device which includes the element.

Due to the presence of elements such as a front camera, a light-transmitting region of the display panel needs to have a high transmittance, and in order to increase the transmittance of the light-transmitting region, pixel circuits for driving the light emission of pixel units in the light-transmitting region are generally arranged outside a photosensitive region.

The corresponding luminous brightnesses of different pixel units in the light-transmitting region are generally different, resulting in the problem of non-uniform display. This is due to the fact that when the pixel circuits are moved out of the light-transmitting region, paths between the pixel units and the pixel circuits located outside the light-transmitting region become longer, and spacings between different pixel units located at different positions in the light-transmitting region and corresponding pixel circuits are different, and the lengths of the traces for connecting the corresponding pixel units and the pixel circuits are different, and the different lengths of the traces would lead to different capacitances. Generally, a longer trace path produces a larger capacitance than a shorter trace, thereby having a greater influence on the charging and discharging time of the pixel unit, and thus causing a greater reduction in the luminous brightness of the pixel unit. Compared to the case where the pixel circuits are located in the light-transmitting region, the luminous brightnesses of the pixel unit far away from a corresponding pixel circuit is significantly reduced, and the luminous brightnesses of the pixel unit close to the corresponding pixel circuit is less reduced, and the luminous brightnesses of different pixel units are reduced to different extents, resulting in the problem of non-uniform display.

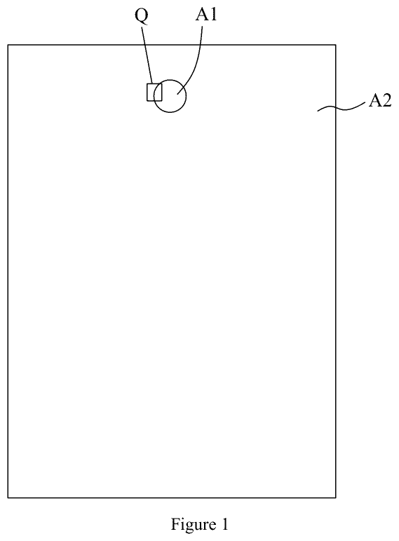

In order to solve the above problem, referring to FIGS. 1 to 3, the embodiments of the present application provide a display panel having a first area A1 and a second area A2. The first area A1 has a transmittance greater than the transmittance of the second area A2. The display panel includes a first pixel unit P1, a second pixel unit P2, a first pixel circuit D1, a second pixel circuit D2, and a first wire 10.

The first pixel unit P1 and the second pixel unit P2 are both arranged in the first area A1, and the first pixel circuit D1 is located in the second area A2 and connected to the first pixel unit P1. The second pixel circuit D2 is located in the second area A2 and connected to the second pixel unit P2. A distance between the second pixel circuit D2 and the second pixel unit P2 is greater than a distance between the first pixel circuit D1 and the first pixel unit P1. The first wire 10 is at least partially used to connect the first pixel unit P1 and the first pixel circuit D1. The first wire 10 has a length greater than the distance between the first pixel circuit D1 and the first pixel unit P1.

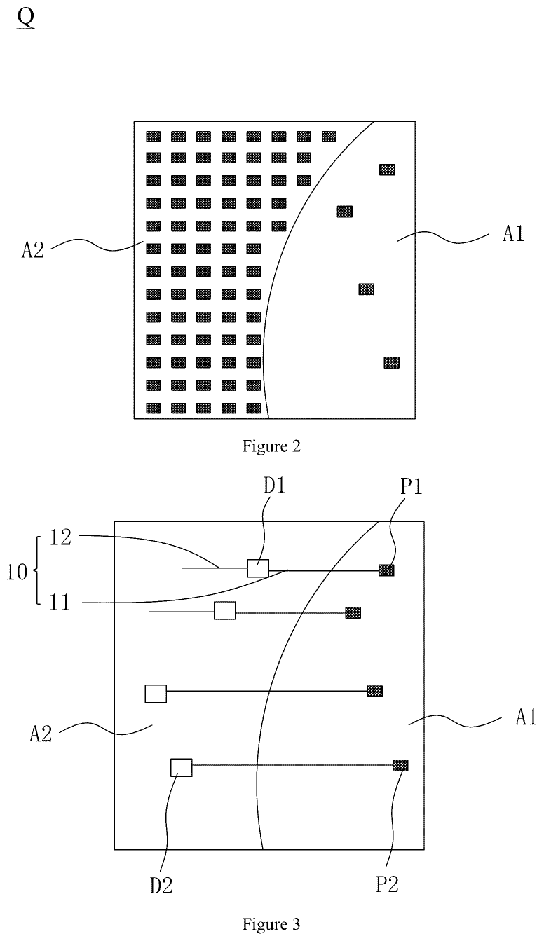

FIG. 1 shows a schematic top view of a display panel according to an embodiment of the present application, FIG. 2 is a structural schematic partial enlarged view of a region Q in FIG. 1, and FIG. 3 is a structural schematic partial enlarged view of the region Q in FIG. 1 in another example. FIGS. 3 and 2 illustrate different layer structures. The arrangement of the first pixel unit P1 and the second pixel unit P2 in the region Q is illustrated in FIG. 2. FIG. 3 is different from FIG. 2 in that FIG. 3 illustrates the structural diagram of the arrangement of the first pixel circuit D1 and the second pixel circuit D2, and retains a plurality of first pixel units P1 and second pixel units P2 in the first area A1.

The display panel has at least a first area A1 and a second area A2. The first area A1 is a light-transmitting area of the display panel. A photosensitive element is provided in the first area A1. The photosensitive element includes, but is not limited to, a front camera and an infrared sensing element. Moreover, a plurality of pixel units are further provided in the first area A1. By way of example, a first pixel unit P1 and a second pixel unit P2 are provided, to enable the first area A1 to serve a display function, to meet the requirement of full screen. The shape of the first area A1 is not limited in the embodiments of the present application. By way of example, the outline of the first area A1 may be circular, square, polygonal, droplet-like, etc.

The second area A2 surrounds an outer peripheral side of the first area A1, and the second area A2 is a main active area of the display panel. That is, pixel units are also provided in the second area A2. In general, in order to achieve the light transmission function of the first area A1, the transmittance of the first area A1 is set to be greater than the transmittance of the second area A2. By way of example, the densities of the first pixel units P1 and the second pixel units P2 in the first area A1 may be appropriately reduced to increase the transmittance of the first area A1. In one embodiment, it is also possible to reduce the size of the first pixel units P1 in the first area A1, thereby increasing the transmittance of the first area A1. In this embodiment, the second area A2 surrounding the outer peripheral side of the first area A1 may mean that the first area A1 is adjacent to either side of the second area A2, or located inside the second area A2.

The first pixel unit P1 and the second pixel unit P2 are both located in the first area A1, and both can emit light to achieve the display effect of the first area A1. The first pixel circuit D1 is configured to drive the first pixel unit P1 in the first area A1 to implement the light-emitting function, and the second pixel circuit D2 is configured to drive the second pixel unit P2 in the first area A1 to implement the light-emitting function. The structures of the first pixel circuit D1 and the second pixel circuit D2 are not limited in the embodiments of the present application. By way of example, the first pixel circuit D1 may take the form of 7T1C, 8T1C, etc., and the second pixel circuit D2 may take the same form and structure as the first pixel circuit D1, or may take a different form and structure from the first pixel circuit D1.

Since the presence of the first pixel circuit D1 and the second pixel circuit D2 reduces the transmittance at the corresponding position of the display panel, the first pixel circuit D1 and the second pixel circuit D2 are both arranged in the second area A2, i.e., outside the first area A1 in the embodiments of the present application. Such a design can reduce the influence of the first pixel circuit D1 and the second pixel circuit D2 on the transmittance of the first area A1, and thus can achieve a better light transmission effect of the first area A1. The first pixel circuit D1 and the second pixel circuit D2 may be located on the same side with respect to the first area A1, or may be on different sides with respect to the first area A1. This is not limited in the embodiments of the present application.

The first pixel circuit D1 is connected to the first pixel unit P1, the second pixel circuit D2 is connected to the second pixel unit P2, and the distance between the second pixel circuit D2 and the second pixel unit P2 is greater than the distance between the first pixel circuit D1 and the first pixel unit P1. For pixel circuits and pixel units at different distances, the lengths of wires used to connect the pixel units and the pixel circuit are generally different.

Specifically, the length of the wire used to connect the second pixel circuit D2 and the second pixel unit P2 is generally the same as or similar to the distance between the second pixel circuit D2 and the second pixel unit P2, and the length of the wire used to connect the first pixel circuit D1 and the first pixel unit P1 is generally the same as or similar to the distance between the first pixel circuit D1 and the first pixel unit P1. As a result, the length of the wire used to connect the second pixel circuit D2 and the second pixel unit P2 is greater than the length of the wire used to connect the first pixel circuit D1 and the first pixel unit P1. The difference in the lengths of the wires results in a difference in the values of capacitance generated between the wires and the other conductive layers, and the value of capacitance between the longer wire used to connect the second pixel circuit D2 and the second pixel unit P2 and a surrounding conductive layer is generally greater than the value of the capacitance between the shorter wire used to connect the first pixel circuit D1 and the first pixel unit P1 and a surrounding conductive layer. The difference in the values of capacitance results in a difference in the pixel charging and discharging time, which in turn makes the luminous brightness of the second pixel unit P2 lower than that of the first pixel unit P1 under the same conditions.

It should be noted that the first pixel unit P1 and the second pixel unit P2 mentioned in the embodiments of the present application refer to two pixel units located in the first area A1 and at different distances from the corresponding pixel circuits. That is, each of the number of first pixel units P1 and the number of second pixel units P2 may be one or more, as long as the distance between the first pixel unit P1 and the first pixel circuit D1 is smaller than the distance between the second pixel unit P2 and the second pixel circuit D2. The first pixel unit P1 and the second pixel unit P2 may have the same or different characteristics in terms of their luminous color, size, shape, etc. This is not limited in the embodiments of the present application.

The first wire 10 is at least partially connected to the first pixel unit P1 and the first pixel circuit D1, the first wire 10 may be a single trace structure and have two ends connected to the first pixel unit P1 and the first pixel circuit D1, respectively, to implement the electrical connection between the first pixel unit P1 and the first pixel circuit D1. In one embodiment, the first wire 10 may include a plurality of trace structures, some of which are configured to electrically connect the first pixel unit P1 and the first pixel circuit D1.

The first wire 10 has a length greater than the distance between the first pixel circuit D1 and the first pixel unit P1. The length of the first wire 10 mentioned in the embodiments of the present application is the sum of the extension lengths of all the structures in the first wire 10. When the first wire 10 includes a plurality of trace structures, the length of the first wire 10 is the sum of the extension lengths of all the trace structures. The distance between the first pixel circuit D1 and the first pixel unit P1 mentioned in the embodiments of the present application is the shortest straight-line distance between the first pixel circuit D1 and the first pixel unit P1.

For the first wire 10, the length of the first wire 10 may be increased by increasing the number of trace structures of the first wire 10. In one embodiment, the length of the first wire 10 may be increased by changing the extension direction of a portion of the first wire 10, that is, the first wire 10 is not connected in the form of a straight line to the first pixel circuit D1 and the first pixel unit P1.

In an embodiment of the present application, the length of the first wire 10 is increased to be greater than the distance between the first pixel circuit D1 and the first pixel unit P1, and the value of capacitance corresponding to the first wire 10 is greater than the value of capacitance corresponding to the trace used to connect the first pixel circuit D1 and the first pixel unit P1. Such a design can reduce the difference in the lengths of the respective trace of the first pixel unit P1 and the respective trace of the second pixel unit P2, thereby reducing the difference in the values of capacitance corresponding thereto, reducing the difference in charging time between the first pixel unit P1 and the second pixel unit P2, making the luminous brightness of the first pixel unit close to that of the second pixel unit P2, and improving the display uniformity of the first area A1.

In some embodiments, referring to FIGS. 3 to 5, the first wire 10 includes a first section 11 between the first pixel unit P1 and the first pixel circuit D1. The first section 11 is used to connect the first pixel unit P1 and the first pixel circuit D1. The first wire 10 further includes a second section 12. One end of the second section 12 is connected to at least one of the first pixel circuit D1 and the first pixel unit P1.

The first wire 10 includes the first section 11 and the second section 12. The first section 11 is configured to implement an electrical connection between the first pixel circuit D1 and the first pixel unit P1, and the first section 11 may be in the form of a straight line, or may be in the form of a polyline, a curve, etc.

The second section 12 includes two opposite ends, one of which is connected to one of the first pixel circuit D1 and the first pixel unit P1, and the second section 12 and the first section 11 are electrically connected to each other and thus have the same potential. The other end of the second section 12 may be connected to the other one of the first pixel circuit D1 and the first pixel unit P1, or may be connected to neither of the first pixel circuit D1 and the first pixel unit P1.

In the embodiments of the present application, by additionally providing the second section 12 on the basis of the first section 11 and by connecting the second section 12 to at least one of the first pixel circuit D1 and the first pixel unit P1, the overall length of the first wire 10 is increased, the capacitance generated corresponding to the second section 12 can increase the overall value of capacitance corresponding to the first wire 10, thereby reducing the difference in the luminous brightnesses of the first pixel unit P1 and the second pixel unit P2, and improving display uniformity.

It should be noted that the first section 11 and second section 12 may be located in the same film layer or may be located in different film layers. This is not limited in the embodiments of the present application.

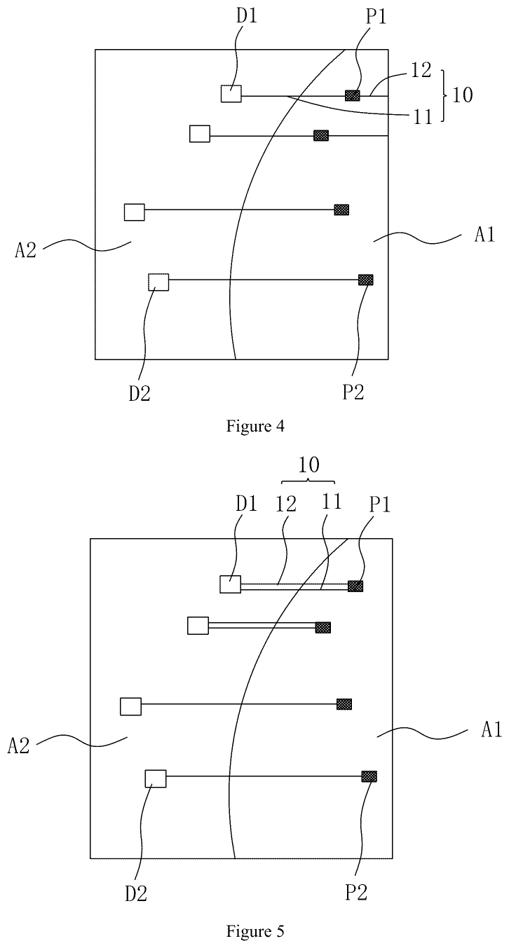

In some embodiments, as shown in FIGS. 3 and 4, the other end of the second section 12 is floated.

The term “floated” mentioned in the embodiments of the present application means that one end of the second section 12 is spaced apart from other conductive structures in the display panel. That is, one end of the second section 12 is neither electrically connected to the first pixel circuit D1 and the first pixel unit P1, nor electrically connected to the other conductive structures in the display panel, and is thus insulated and separated from the other conductive structures in the display panel.

In summary, in the embodiments of the present application, the second section 12 has one end electrically connected to one of the first pixel circuit D1 and the first pixel unit P1, and the other end insulated from the conductive structures in the display panel, and the presence of the second section 12 can increase the value of capacitance corresponding to the first wire 10, and reduce the difference in the luminous brightnesses of the first pixel unit P1 and the second pixel unit P2. Moreover, the presence of the second section 12 will not influence the other conductive structures in the display panel, avoid the risk of signal crosstalk, and improve the use reliability of the display panel.

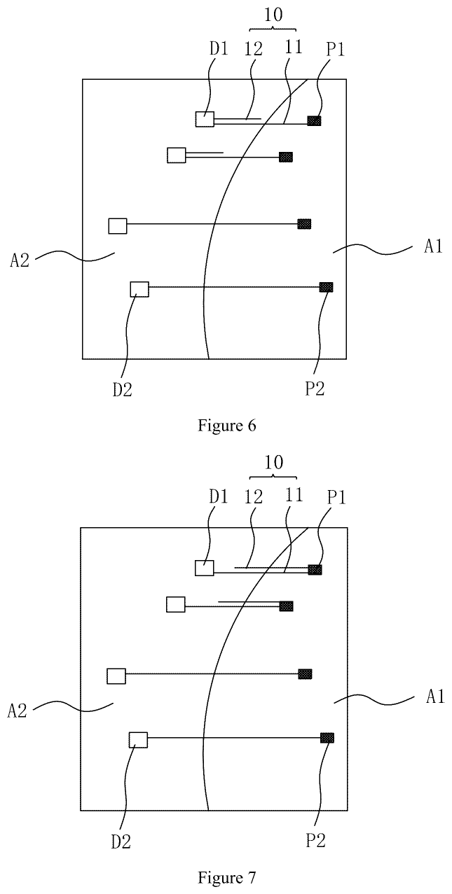

In some embodiments, referring to FIGS. 3 and 6, one end of the second section 12 is connected to the first pixel circuit D1 and the other end of the second section 12 is floated. As shown in FIG. 3, the second section 12 extends in a direction away from the first pixel unit P1, or as shown in FIG. 6, the second section 12 extends in a direction close to the first pixel unit P1.

The second section 12 has one end connected to the first pixel circuit D1 and the other end floated, i.e. the other end of the second section 12 is not electrically connected to the first pixel unit P1. On this basis, the second section 12 may be arranged to extend in the direction close to the first pixel unit P1, that is, the second section 12 is arranged between the first pixel unit P1 and the first pixel circuit D1. The second section 12 may be arranged to extend in the direction away from the first pixel unit P1, that is, the second section 12 is arranged on a side of the first pixel circuit D1 away from the first pixel unit P1. The specific arrangement of the second section 12 needs to be determined according to the actual requirements of the display panel. This is not limited in the embodiments of the present application.

For the embodiment in which the second section 12 extends in the direction close to the first pixel unit P1, since the first pixel unit P1 is located in the first area A1 and the first pixel circuit D1 is located in the second area A2, in one embodiment, the second section 12 may be arranged only in the second area A2 in order to reduce the influence of the first wire 10 on the transmittance of the first area A1, thereby preventing the second section 12 from affecting the transmittance of the first area A1, and thus indirectly improving the effect of light transmission of the display panel.

For the embodiment in which the second section 12 extends in the direction away from the first pixel unit P1, since the traces are generally gathered between the pixel unit and the pixel circuit, the second section 12 being arranged on the side of the first pixel circuit D1 away from the first pixel unit P1 can reduce the density of the traces between the first pixel circuit D1 and the first pixel unit P1, thereby reducing the risk of signal crosstalk between the traces.

In some embodiments, referring to FIGS. 4 and 7, one end of the second section 12 is connected to the first pixel unit P1 and the other end of the second section 12 is floated. As shown in FIG. 4, the second section 12 extends in a direction away from the first pixel circuit D1, or as shown in FIG. 7, the second section 12 extends in a direction close to the first pixel circuit D1.

The second section 12 has one end connected to the first pixel unit P1 and the other end floated, i.e. the other end of the second section 12 is not electrically connected to the first pixel circuit D1. On this basis, the second section 12 may be arranged to extend in the direction close to the first pixel circuit D1, that is, the second section 12 is arranged between the first pixel unit P1 and the first pixel circuit D1. The second section 12 may be arranged to extend in the direction away from the first pixel circuit D1, that is, the second section 12 is arranged on a side of the first pixel unit P1 away from the first pixel circuit D1. The specific arrangement of the second section 12 needs to be determined according to the actual requirements of the display panel. This is not limited in the embodiments of the present application.

It should be noted that the first pixel unit P1 is generally formed of a plurality of film layers stacked on one another. By way of example, the first pixel unit P1 includes an anode layer, a hole injection layer, a hole transport layer, a light-emitting layer, an electron transport layer, an electron injection layer, and a cathode layer stacked on one another. The first section 11 and the second section 12 may both be connected to the anode layer of the first pixel unit P1, to implement mutual conduction between the first pixel circuit D1, the first section 11, the anode layer of the first pixel unit P1 and the second section 12.

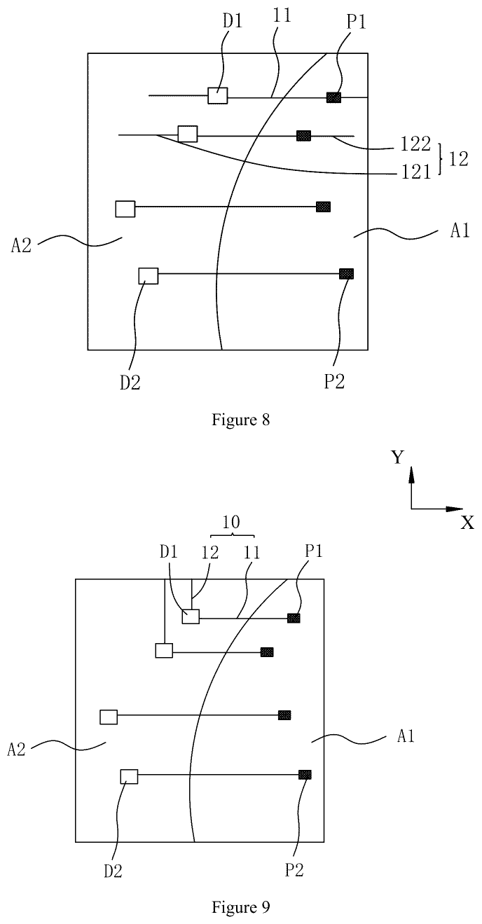

In some embodiments, referring to FIG. 8, the second section 12 includes a first segment 121 and a second segment 122. One end of the first segment 121 is connected to the first pixel circuit D1, and the other end of the first segment 121 is floated. The first segment 121 extends in the direction away from the first pixel unit P1, or in the direction close to the first pixel unit P1. The second segment 122 has one end connected to the first pixel unit P1 and the other end floated, and the second segment 122 extends in the direction away from the first pixel circuit D1 or in the direction close to the first pixel circuit D1.

The second section 12 includes at least the first segment 121 and the second segment 122. The first segment 121 is connected to the first pixel circuit D1 and the second segment 122 is connected to the first pixel unit P1. The first segment 121 may be located between the first pixel circuit D1 and the first pixel unit P1, or may be located on the side of the first pixel circuit D1 away from the first pixel unit P1. Similarly, the second segment 122 may be located between the first pixel circuit D1 and the first pixel unit P1, or may be located on the side of the first pixel unit P1 away from the first pixel circuit D1. By way of example, the first segment 121 and the second segment 122 are both located between the first pixel circuit D1 and the first pixel unit P1; or the first segment 121 is located on the side of the first pixel circuit D1 away from the first pixel unit P1, while the second segment 122 is located on the side of the first pixel unit P1 away from the first pixel circuit D1.

In the embodiments of the present application, the second section 12 includes both the first segment 121 and the second segment 122, the presence of either of the first segment 121 and the second segment 122 can have the effect of increasing the corresponding value of capacitance of the first wire, thereby further reducing the difference in the luminous brightnesses of the first pixel unit P1 and the second pixel unit P2, and improving display uniformity.

In some embodiments, referring to FIG. 9, the first pixel circuit D1 is located on a side of the first pixel unit P1 in a first direction X, and the second section 12 extends in a second direction Y. The first direction X intersects the second direction Y.

The first pixel circuit D1 is arranged opposite the first pixel unit P1 in the first direction X, and the first section 11 may extend in the first direction X and is connected to the first pixel circuit D1 and the first pixel unit P1, respectively. The second section 12 extends in the second direction Y and is connected to one of the first pixel circuit D1 and the first pixel unit P1. By the first direction X intersecting the second direction Y, it is meant that there is an angle between the first direction X and the second direction Y. The angle between the first direction and the second direction Y includes, but is not limited to, 60°, 90°, and 120°. By way of example, the first direction X is perpendicular to the second direction Y, that is, the angle between the first direction X and the second direction Y is 90°.

Since the second section 12 extends in the second direction Y, it is possible to prevent the second section 12 from being sandwiched between the first pixel circuit D1 and the first pixel unit P1. Specifically, taking the case where the first direction X and the second direction Y are perpendicular to each other as an example, the first direction X may be the row direction of the display panel, and the second direction Y is accordingly the column direction of the display panel. The first pixel unit P1 and the first pixel circuit D1 are spaced apart from each other in the row direction of the display panel, and the second section 12 extends in the column direction of the display panel, and the second section 12 is not located between the first pixel circuit D1 and the first pixel unit P1. In general, there are many trace structures in the region between the first pixel circuit D1 and the first pixel unit P1, whereas the embodiment in which the second section 12 extends in the second direction Y in the embodiments of the present application can reduce the influence of the second section 12 on the density of the traces in the region between the first pixel circuit D1 and the first pixel unit P1, thereby reducing the risk of signal crosstalk, and improving display reliability.

In some embodiments, as shown in FIG. 5, two ends of the second section 12 are connected to the first pixel circuit D1 and to the first pixel unit P1, respectively.

The second section 12 is located between the first pixel circuit D1 and the first pixel unit P1, with two ends of the second section 12 being connected to the first pixel unit P1 and the first pixel circuit D1, respectively. Like the first section 11, the presence of the second section 12 can also have the effect of connecting the first pixel circuit D1 and the first pixel unit P1. In addition, the presence of the second section 12 can have the effect of increasing the value of capacitance corresponding to the first wire 10, thereby reducing the difference in the brightnesses of the first pixel unit P1 and the second pixel unit P2, and improving display uniformity.

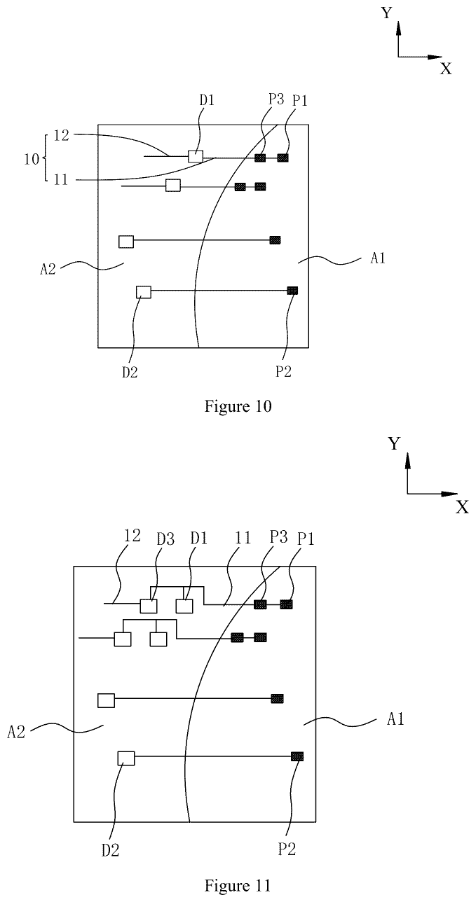

In some embodiments, referring to FIG. 10, the display panel further includes a third pixel unit P3 located in the first area A1. The third pixel unit P3 is arranged between the first pixel unit P1 and the first pixel circuit D1 and connected to the first section 11.

The third pixel unit P3 and the first pixel unit P1 are both located in the first area A1, and the size and shape of the third pixel unit P3 may be the same as or different from the size and shape of the first pixel unit P1. The third pixel unit P3 is sandwiched between the first pixel circuit D1 and the first pixel unit P1, and the first pixel circuit D1 is connected to both the first pixel unit P1 and the third pixel unit P3, thereby driving both the first pixel unit P1 and the third pixel unit P3 to emit light.

In the embodiments of the present application, one first pixel circuit D1 can drive both the first pixel unit P1 and the third pixel unit P3 to emit light. Such a design can reduce the total number of pixel circuits configured to drive the pixel units in the first area A1 to emit light, thereby reducing the number of traces configured to drive the pixel units in the first area A1, i.e., reducing the density of the traces and improving the reliability of signal transfer.

It should be noted that in the embodiments of the present application, there may be one or more third pixel units P3. In one embodiment, there are a plurality of third pixel units P3. Such a design can enable the first wire 10 to control more pixel units simultaneously, further reducing the density of the traces in the display panel.

In some embodiments, referring to FIG. 11, the display panel further includes a third pixel circuit D3 located in the second area A2. The third pixel circuit D3 is arranged between the first pixel unit P1 and the first pixel circuit D1 and connected to the first section 11. It is also possible that the third pixel circuit D3 is arranged outside the first pixel circuit D1 and connected to the first pixel circuit D1.

The third pixel circuit D3 and the first pixel circuit D1 are both located in the second area A2, and the third pixel circuit D3 has various structural forms. By way of example, the third pixel circuit D3 may take the form of 7T1C, 8T1C, etc. The structure of the third pixel circuit D3 may be the same as or different from the structure of the first pixel circuit D1. The third pixel circuit D3 is sandwiched between the first pixel circuit D1 and the first pixel unit P1, and the first pixel circuit D1 and the third pixel circuit D3 are used together to drive the first pixel unit P1 to emit light, and a plurality of pixel circuits together drive a single pixel unit.

The first pixel circuit D1 and the third pixel circuit D3 can together drive the first pixel unit P1 to emit light. There may be one or more third pixel circuits D3. In one embodiment, there are a plurality of third pixel circuits D3.

It should be noted that a third pixel unit P3 may also be provided between the third pixel circuit D3 and the first pixel unit P1, that is, the first pixel circuit D1 and the third pixel circuit D3 together drive the first pixel unit P1 and the third pixel unit P3 to emit light. In other words, in the embodiments of the present application, the first wire 10 may be applied to an embodiment in which one pixel circuit drives one pixel unit, to an embodiment in which one pixel circuit drives a plurality of pixel units, to an embodiment in which a plurality of pixel circuits drive one pixel unit, or to an embodiment in which a plurality of pixel circuits drive a plurality of pixel units.

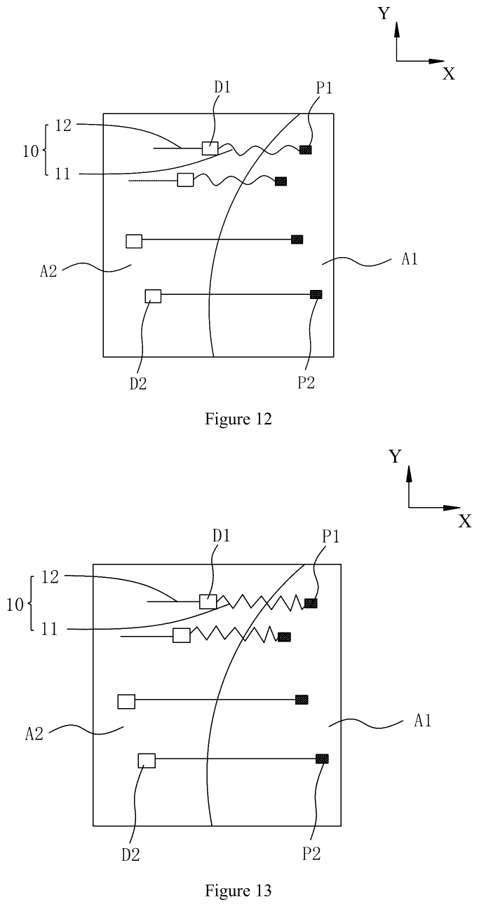

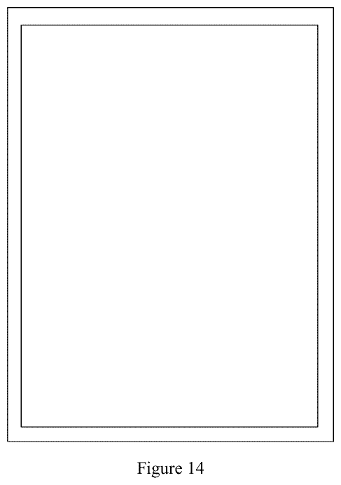

In some embodiments, referring to FIGS. 12 and 13, the first pixel circuit D1 is located on a side of the first pixel unit P1 in a first direction X, and an extension direction of at least a portion of the first section 11 intersects the first direction X.

It can be seen from the foregoing that the first section 11 is located between the first pixel circuit D1 and the first pixel unit P1, for implementing an electrical connection between the first pixel circuit D1 and the first pixel unit P1. On this basis, since the first pixel circuit D1 and the first pixel unit P1 are spaced apart from each other in the first direction X, and the extension direction of at least a portion of the first section 11 intersects the first direction X, the first section 11 is not a single straight-line structure extending along the first direction X. Such a design can increase the length of the first section 11, thereby increasing the value of capacitance corresponding to the first wire 10, reducing the difference in the brightnesses of the first pixel unit P1 and the second pixel unit P2, and improving display uniformity.

It should be noted that the extension direction of a partial structure of the first section 11 may be parallel to the first direction X, or the extension direction at any position of the first section 11 intersects the first direction X. This is not limited in the embodiments of the present application. In one embodiment, the first section 11 includes at least one of a curve segment and a polyline segment.

In some embodiments, the first section 11 and the second section 12 are located in the same film layer. In one embodiment, the first section 11 and the second section 12 are located in different film layers. That is, the first section 11 and the second section 12 are located at different positions in a thickness direction of the display panel. The first section 11 and the second section 12 may each be made of the same material as the other wire structure located in the same layer, and the first section 11 and the second section 12 may each be manufactured in the same process step as the wire structure in the same layer, thereby simplifying the manufacturing process of the display panel, and improving the production effect.

In the embodiments of the present application, since the distance between the first section 11 and the second section 12 is relatively close, in order to reduce the risk of signal crosstalk between the first section 11 and the second section 12, the first section 11 and the second section 12 are arranged in different film layers in an embodiment of the present application, to improve the reliability of signal transfer.

It should be noted that the positions of the first section 11 and the second section 12 relative to the second wire are not limited in the embodiments of the present application. That is, each of the first section 11 and the second section 12 may be arranged in the same layer as or in a different layer from the second wire. In one embodiment, the display panel further includes a second wire for connecting the second pixel circuit D2 and the second pixel unit P2. The first section 11 and the second wire are located in the same film layer, and the second section 12 and the second wire are located in different film layers. Such a design can enable the first section 11 and the second wire to be formed together in the same manufacturing process, while reducing the signal crosstalk between the first section 11 and the second section 12, thereby simplifying the manufacturing process of the display panel.

In some embodiments, the second section 12 is of a transparent structure or a metallic structure.

The second section 12 needs to be connected to at least one of the first pixel circuit D1 and the first pixel unit P1, and they are electrically connected to each other. On this basis, the second section 12 can be formed of a variety of materials, which may be the same as the material of the first section 11 or different from the material of the first section 11.

Specifically, when the second section 12 is of a transparent material, it is possible to reduce the influence of the second section 12 on the transmittance at the corresponding position of the display panel, and to improve the light transmission effect of the display panel. By way of example, the material of the second section 12 includes at least one of indium tin oxide, indium zinc oxide, silver-doped indium tin oxide and silver-doped indium zinc oxide.

When the second section 12 is of a metallic structure, the metallic structure can improve the effect of signal transfer between the second section 12 and at least one of the first pixel circuit D1 and the first pixel unit P1, thereby better satisfying the display requirements. By way of example, the material of the second section 12 includes at least one of titanium, aluminum, copper, silver and magnesium.

In some embodiments, a total capacitor formed between the first wire 10 and a conductive layer surrounding the first wire on the display panel is defined as a first capacitor having a first value of capacitance C1. A total capacitor formed between the second wire and a conductive layer surrounding the second wire on the display panel is defined as a second capacitor having a second value of capacitance C2. C1 and C2 satisfy: 0.3≤C1/C2≤1. By way of example, C1/C2 may be one of 0.3, 0.5, 0.7, and 1.

It can be seen from the foregoing that the first wire 10 in the embodiments of the present application can have a longer dimension than the trace used to connect the first pixel unit P1 and the first pixel circuit D1, and the difference between the first value of capacitance corresponding to the first wire 10 and the second value of capacitance corresponding to the second wire can be reduced, and thus the difference in the brightnesses of the first pixel unit P1 and the second pixel unit P2 can be reduced. In one embodiment, C1 and C2 satisfy: 0.7≤C1/C2≤1.

One embodiment of the present application provides a display device, including a display panel in any one of the above embodiments.

A drive method for the display device described in the present application includes an OTP (One Time Program) operation. Specifically, the pixel units in the first active area A1 are adjusted to a low grayscale state, in which the Gamma value is adjusted to obtain a correct Gamma curve, which is then burned into an IC. Since the values of the brightnesses of the pixel units in the first active area in the embodiments of the present disclosure are close, it is possible to easily increase the consistency of the pixel units in the first active area, to achieve uniform display brightness. It should be noted that the display device provided in the embodiments of the present application has the beneficial effects of the display panel in any one of the above embodiments. Reference is made to the above description of the beneficial effects of the display panel for details, which will not be repeated in the embodiments of the present application.

Although the embodiments disclosed in the present application are as described above, the content described is only embodiments used to facilitate the understanding of the present application rather than to limit the present disclosure. Any modification and variation in the form and details of implementation without departing from the spirit and scope disclosed in the present application, but the scope of protection of the present application shall still be subject to the scope defined by the appended claims.

The above descriptions are merely specific embodiments of the present application. For convenience and brevity of description, for replacement of other connection manners described above, reference may be made to the corresponding processes in the above method embodiments, and details are not repeated herein. It should be understood that the scope of protection of the present application is not limited thereto, any equivalent modification or replacement that can be easily conceived within the scope disclosed in the present application in the art shall fall within the scope of protection of the present application.

What is claimed is:

1. A display panel having a first area and a second area, the first area having a transmittance greater than the transmittance of the second area, the display panel comprising:
a first pixel unit arranged in the first area;
a second pixel unit arranged in the first area;
a first pixel circuit located in the second area and connected to the first pixel unit;
a second pixel circuit located in the second area and connected to the second pixel unit, a distance between the second pixel circuit and the second pixel unit being greater than a distance between the first pixel circuit and the first pixel unit; and
a first wire at least partially for connecting the first pixel unit and the first pixel circuit, the first wire having a length greater than the distance between the first pixel circuit and the first pixel unit.

2. The display panel according to claim 1, wherein the first wire comprises a first section between the first pixel unit and the first pixel circuit, the first section being configured to connect the first pixel unit and the first pixel circuit; and
the first wire further comprises a second section, one end of the second section being connected to one of the first pixel circuit and the first pixel unit.

3. The display panel according to claim 2, wherein the other end of the second section is floated.

4. The display panel according to claim 3, wherein one end of the second section is connected to the first pixel circuit, and the other end of the second section is floated; and
starting from the end connected to the first pixel circuit, the second section extends in a direction away from the first pixel unit, or in a direction close to the first pixel unit.

5. The display panel according to claim 3, wherein one end of the second section is connected to the first pixel unit, and the other end of the second section is floated; and starting from the end connected to the first pixel unit, the second section extends in a direction away from the first pixel circuit, or in a direction close to the first pixel circuit.

6. The display panel according to claim 3, wherein the second section comprises a first segment and a second segment,
one end of the first segment is connected to the first pixel circuit, the other end of the first segment is floated, and starting from the end connected to the first pixel circuit, the first segment extends in a direction away from the first pixel unit, or in a direction close to the first pixel unit; and
one end of the second segment is connected to the first pixel unit, the other end of the second segment is floated, and starting from the end connected to the first pixel unit, the second segment extends in a direction away from the first pixel circuit, or in a direction close to the first pixel circuit.

7. The display panel according to claim 3, wherein the first pixel circuit is located on a side of the first pixel unit in a first direction, and the second section extends in a second direction, the first direction intersecting the second direction.

8. The display panel according to claim 2, wherein two ends of the second section are connected to the first pixel circuit and the first pixel unit, respectively.

9. The display panel according to claim 2, further comprising at least one third pixel unit located in the first area, wherein the at least one third pixel unit is arranged between the first pixel unit and the first pixel circuit and connected to the first section.

10. The display panel according to claim 9, further comprising at least one third pixel circuit located in the second area, wherein the at least one third pixel circuit is arranged between the first pixel unit and the first pixel circuit and connected to the first section.

11. The display panel according to claim 10, wherein the at least one third pixel unit comprises a plurality of third pixel units; and
the at least one third pixel circuit comprises a plurality of third pixel circuits.

12. The display panel according to claim 2, wherein the first pixel circuit is located on a side of the first pixel unit in a first direction, and at least a portion of the first section extends in a direction intersecting the first direction to increase capacitance.

13. The display panel according to claim 12, wherein the first section comprises at least one of a curve segment and a polyline segment.

14. The display panel according to claim 2, wherein the first section and the second section are located in a same film layer or in different film layers.

15. The display panel according to claim 14, further comprising a second wire for connecting the second pixel circuit and the second pixel unit, the second section and the second wire being located in different film layers.

16. The display panel according to claim 15, wherein the first section and the second wire are located in a same film layer.

17. The display panel according to claim 2, wherein the second section is of a transparent structure or a metallic structure.

18. The display panel according to claim 17, wherein the second section is of a transparent structure, and a material of the second section comprises at least one of indium tin oxide, indium zinc oxide, silver-doped indium tin oxide and silver-doped indium zinc oxide; or
the second section is of a metallic structure, and the material of the second section comprises at least one of titanium, aluminum, copper, silver and magnesium.

19. The display panel according to claim 1, wherein the first wire and a conductive layer surrounding the first wire form a first capacitor on the display panel, the first capacitor having a first value of capacitance C1; and
the display panel further comprises a second wire for connecting the second pixel circuit and the second pixel unit, and the second wire and a conductive layer surrounding the second wire form a second capacitor on the display panel, the second capacitor having a second value of capacitance C2,
wherein C1 and C2 satisfy: 0.3≤C1/C2≤1.

20. A display device, comprising:
a display panel having a first area and a second area, the first area having a transmittance greater than the transmittance of the second area, the display panel comprising:
a first pixel unit arranged in the first area;
a second pixel unit arranged in the first area;
a first pixel circuit located in the second area and connected to the first pixel unit;
a second pixel circuit located in the second area and connected to the second pixel unit, a distance between the second pixel circuit and the second pixel unit being greater than a distance between the first pixel circuit and the first pixel unit; and
a first wire at least partially for connecting the first pixel unit and the first pixel circuit, the first wire having a length greater than the distance between the first pixel circuit and the first pixel unit.
